(19) United States
(12) Patent Application Publication
(10) Pub. No.: US 2026/0031285 A1
(43) Pub. Date: Jan. 29, 2026

(54) Shape Memory Alloy Sensing And Actuation Switch

(71) Applicant: Hutchinson Technology Incorporated, Hutchinson, MN (US)

(72) Inventors: Michael E. Roen, Hutchinson, MN (US); Richard A. Schnitzler, Dassel, MN (US); Ryan N. Ruzicka, Waconia, MN (US); Mark M. Rickertsen, Hutchinson, MN (US)

(21) Appl. No.: 19/278,646

(22) Filed: Jul. 23, 2025

Related U.S. Application Data
(60) Provisional application No. 63/676,794, filed on Jul. 29, 2024.

(51) Int. Cl. H01H 9/54; G01R 19/00

(52) U.S. Cl. CPC H01H 9/54; G01R 19/0092

(57) ABSTRACT

The present embodiments relate to a shape memory alloy (SMA) sensor being part of a switch. For instance, an SMA sensor can include an actuator configured to engage with a locking mechanism that modifies the resistance of the SMA sensor when the locking mechanism is in the locked position. The resistance of the SMA sensor can be unmodified by an external magnetic field, increasing reliability of the SMA sensor resistance determining a state of the locking mechanism. Another example, SMA sensor is an SMA wire being in contact with a locking mechanism in the locked position, thereby increasing a resistance of the SMA wire in the locked position.

### CROSS-REFERENCE TO RELATED APPLICATION(S)

This application claims the benefit of, and priority to, U.S. Provisional Application No. 63/676,794 filed on Jul. 29, 2024, which is hereby incorporated by reference in its entirety.

### TECHNICAL FIELD

Embodiments of the invention relate to the field of shape memory alloy systems. More particularly, embodiments of the invention relate to shape memory alloy sensor switch devices and methods related thereto.

### BACKGROUND

Shape memory alloy (“SMA”) systems can include an actuator or structure that can be used in conjunction with various components. The SMA actuator can be configured to actuate responsive to providing an electrical current to the SMA wire.

For example, a first end of an SMA wire can be engaged at a fixed end fixed to a base. Further, a second end of the SMA wire can be engaged to a free end configured to move in response to the actuation of the SMA wire. For instance, the free end can move in a positive direction in response to the actuation of the SMA wire.

### SUMMARY

The present embodiments relate to a shape memory alloy (SMA) sensor being part of a switch. For instance, an SMA sensor can include an actuator configured to engage with a locking or moving mechanism that modifies the resistance of the SMA sensor when the locking or moving mechanism is in the locked or closed position. The resistance of the SMA sensor can be unmodified by an external magnetic field, increasing reliability of the SMA sensor resistance determining a state of the locking or moving mechanism. Also, the resistance of an SMA sensor is impervious to contact resistance typical in many electrical switches. Also, the resistance of an SMA sensor has no contact resistance as is typical in many electrical switches. Another example, SMA sensor is an SMA wire being in contact with a locking or moving mechanism in the locked or closed position, thereby increasing or changing a resistance of the SMA wire in the locked or closed position.

In a first example embodiment, a lock or sensor system is provided. The lock or sensor system can include a locking or moving mechanism configured to be disposed in any of a locked or closed position and an unlocked or open position. The lock or sensor system can also include a shape memory alloy (SMA) sensor configured to move in response to a current being applied to the SMA sensor. The locking or moving mechanism can be configured to restrict movement of the SMA sensor or increase or change a resistance of the SMA sensor in the locked or closed position, and a locked or closed resistance of the SMA sensor when the locking or moving mechanism is in the locked or closed position is greater than or different than an unlocked or open resistance of the SMA sensor when the locking or moving mechanism is in the unlocked or open position.

In some instances, the locked or closed resistance or the unlocked or open resistance of the SMA sensor is not modified by any external magnetic field applied to the lock or sensor system.

In some instances, the SMA sensor is a bimorph actuator comprising a first bimorph arm including a fixed end fixed to a base, a free end that is unfixed, and an SMA wire disposed from at least the fixed end to the free end, wherein the free end is configured to move in a positive direction in response to the current being applied to the SMA wire.

In some instances, the bimorph actuator further comprises a second bimorph arm with a fixed end fixed to the base and a free end disposed in a direction opposite to a direction of the free end of the first bimorph arm, and wherein the SMA wire is disposed from the free end of the first bimorph arm to the free end of the second bimorph arm.

In some instances, the locking or moving mechanism, in the unlocked or open position, is configured to move laterally away from the SMA sensor to allow free movement of the SMA sensor in response to the current being applied to the SMA sensor.

In some instances, the SMA sensor is an SMA element disposed between anchor points anchored to a base.

In some instances, the locking or moving mechanism is substantially circular with a flat portion, wherein the locking or moving mechanism in the locked or closed position comprises a circular portion of the locking mechanism being in contact with the SMA element, thereby increasing or changing a resistance of the SMA element and deforming the SMA element, and wherein the locking or moving mechanism in the unlocked or open position includes the flat portion being in parallel with the SMA element, reducing or changing the resistance of the SMA element.

In some instances, responsive to the locking or moving mechanism moving from the locked or closed position to the unlocked position or open position, the current applied to the SMA element restored an original shape of the SMA element.

In some instances, the SMA sensor is a buckler actuator comprising a first buckler arm including a fixed end fixed to a base at a first end of the base, and a free end that is unfixed. The buckler actuator can also include a second buckler arm including a fixed end fixed to a second end of the base a free end that is unfixed, wherein the free end of the second buckler arm is directed toward the free end of the first buckler arm and an SMA wire disposed between the first end of the base and the second end of the base.

In some instances, the SMA sensor is a bridge sensor comprising a first portion disposed from a first end of a base to a second end of the base, a second portion disposed in parallel with the first portion and fixed at each of the first end of the base and the second end of the base, and an SMA wire disposed between an opening formed between the first portion and the second portion and extending between the first end of the base and the second end of the base.

In another example embodiment, a device is provided. The device can include a locking or moving mechanism configured to be disposed in any of a locked or closed position and an unlocked or open position. The device can also include a shape memory alloy (SMA) actuator comprising a first actuator arm including a fixed end fixed to a base, a free end that is unfixed, and an SMA wire disposed from at least the fixed end to the free end, wherein the free end is configured to move in a positive direction in response to a current being applied to the SMA wire, wherein the locking or moving mechanism is configured to restrict movement of the SMA actuator or increase or change a resistance of the SMA actuator in the locked or closed position, and wherein a locked or closed resistance of the SMA actuator when the locking or moving mechanism is in the locked or closed position is greater than or different than an unlocked or open resistance of the SMA actuator when the locking or moving mechanism is in the unlocked or open position.

In some instances, the locked or closed resistance or the unlocked or open resistance of the SMA sensor is not modified by any external magnetic field applied to the lock or sensor system.

In some instances, the bimorph actuator further comprises a second actuator arm with a fixed end fixed to the base and a free end disposed in a direction opposite to a direction of the free end of the first actuator arm, and wherein the SMA wire is disposed from the free end of the first actuator arm to the free end of the second actuator arm.

In some instances, the locking or moving mechanism, in the unlocked or open position, is configured to move laterally away from the SMA sensor to allow free movement of the SMA sensor in response to the current being applied to the SMA sensor.

In some instances, the SMA actuator is a buckler actuator comprising a second actuator arm including a fixed end fixed to a second end of the base, a free end that is unfixed, wherein the free end of the second buckler arm is directed toward the free end of the first buckler arm, and an SMA wire disposed between the first end of the base and the second end of the base.

In another example embodiment, a lock or sensor is provided. The lock or sensor can include a locking or moving mechanism configured to be disposed in any of a locked or closed position and an unlocked or open position, wherein the locking or moving mechanism is substantially circular with a flat portion. The lock or sensor can also include a shape memory alloy (SMA) element configured to move in response to a current being applied to the SMA element, wherein the locking or moving mechanism is configured to increase or change a resistance of the SMA element in the locked or closed position, and wherein a locked or closed resistance of the SMA element when the locking or moving mechanism is in the locked or closed position is greater than or different than an unlocked or open resistance of the SMA element when the locking or moving mechanism is in the unlocked or open position.

In some instances, the SMA element disposed between anchor points anchored to a base.

In some instances, the locking or moving mechanism in the locked or closed position comprises a circular portion of the locking or moving mechanism being in contact with the SMA element, thereby increasing or changing a resistance of the SMA element and deforming the SMA element, and wherein the locking or moving mechanism in the unlocked or open position includes the flat portion being in parallel with the SMA element, reducing or changing the resistance of the SMA element.

### BRIEF DESCRIPTION OF THE DRAWINGS

Embodiments of the present invention are illustrated by way of example and not limitation in the figures of the accompanying drawings, in which like references indicate similar elements and in which:

FIG. 1 illustrates an example SMA bimorph actuator according to an embodiment.

FIGS. 2A-2B illustrate example sensor designs for the constrained sensor with the shape memory effect according to an embodiment.

FIGS. 3A-B illustrate example states of the constrained sensor with the shape memory effect according to an embodiment.

FIGS. 4A-B illustrate example views of an SMA wire and a locking mechanism according to an embodiment.

FIGS. 5A-C illustrate examples of a constrained sensor with a super-elastic effect according to an embodiment.

FIGS. 6A-B illustrate example positions of a deformed sensor with a super-elastic effect according to an embodiment.

FIG. 7 illustrates an example buckler actuator according to an embodiment.

FIG. 8 illustrates an example inline bimorph actuator according to an embodiment.

FIG. 9 is an example bridge sensor according to an embodiment.

FIG. 10 illustrates an example for SMA actuation with sensing a status of a mechanism according to an embodiment.

FIG. 11A illustrates a first example algorithm for an SMA sensor to indicate whether a locking mechanism is in a locked or unlocked position according to an embodiment.

FIG. 11B illustrates a second example algorithm for an SMA sensor to indicate whether a locking mechanism is in a locked or unlocked position according to an embodiment.

FIG. 12A is a graphical representation of an example change in resistance over time for different actuator groups according to an embodiment.

FIG. 12B is a graphical representation of an example mask violation of resistance slope profile according to an embodiment.

FIG. 13 is an example flow process for contact sensing of an SMA actuator as described herein according to an embodiment.

### DETAILED DESCRIPTION

The present embodiments relate to a shape memory alloy (SMA) sensor being part of a switch. For instance, an SMA sensor can include an actuator configured to engage with a locking mechanism that modifies the resistance of the SMA sensor when the locking mechanism is in the locked position. The resistance of the SMA sensor can be unmodified by an external magnetic field, increasing reliability of the SMA sensor resistance determining a state of the locking mechanism. Another example, SMA sensor is an SMA wire being in contact with a locking mechanism in the locked position, thereby increasing a resistance of the SMA wire in the locked position.

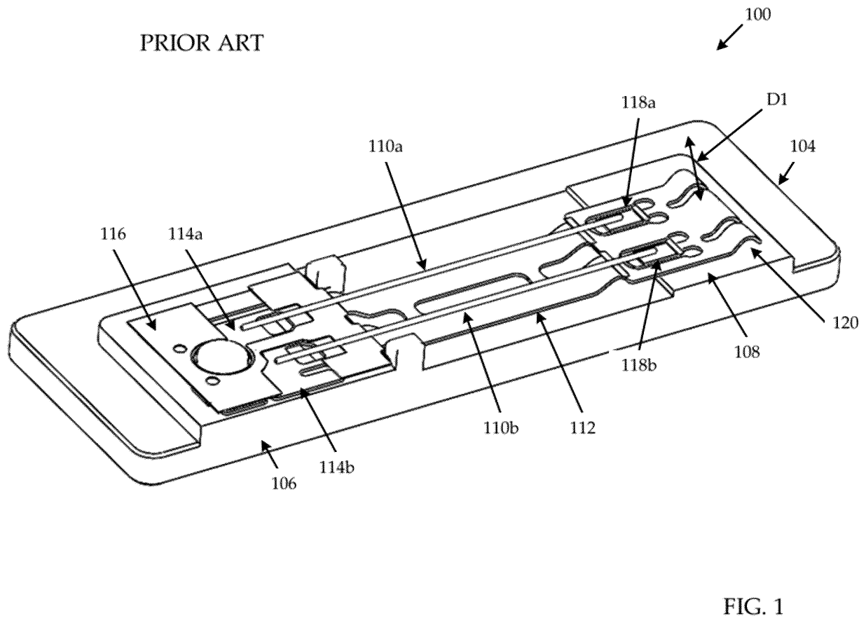

An example of an SMA sensor can include a shape memory alloy (SMA) actuator with a fixed end, a free end, and an SMA wire disposed between the fixed end and free end, which may be referred to as an SMA bimorph actuator. FIG. 1 illustrates an example SMA bimorph actuator 100 according to some embodiments. As shown in FIG. 1, in many cases, the actuator 100 can include a base 120 and a carriage 104. In many instances, the base 120 can be affixed to the carriage 104 as described herein. The carriage 104 can increase resiliency of the actuator 100 by providing support for the base 120.

The base 120 can include a fixed end 106 and a free end 108. The fixed end 106 can be fixed to the carriage 104, while the free end 108 can be detached from the carriage 104. As described in greater detail below, the free end 108 can move in a positive direction (e.g., direction D1) responsive to providing an electrical current to SMA wires 110a, 110b.

As shown in FIG. 1, SMA wires 110a, 110b can extend from the fixed end 106 to the free end 108 of the base 120. Further, a beam 112 can be disposed below the SMA wires 110a, 110b and can connect the fixed end 106 and free end 108. The SMA wires 110a, 110b can connect to the base 120 at each end via electrical contacts. For example, at a first end of each SMA wires 110a, 110b, the SMA wires 110a, 110b can connect to the fixed end 106 at electrical contacts 114a, 114b. Further, at a second end (e.g., at the free end 108), the SMA wires 110a, 110b can connect to the free end 108 at electrical contacts 118a, 118b (e.g., via a welding or soldering process).

The base 120 can consist of a material such as steel or stainless steel, for example. Further, electrical contacts 114a-b, 118a-b can include a material allowing for receiving a welding or soldering joint, such as a gold-plated stainless steel, for example. Further, at fixed end 106, a dielectric 116 can isolate the electrical contacts 114a-b to prevent electrical current between the contacts. Dielectric 116 can include insulative materials, such as a Polyimide, for example. In some embodiments, a dielectric can be disposed between SMA wires 110a-110b and beam 112 at the free end 108 to electrically isolate the SMA wires 110a-b from the beam 112.

In some instances, the actuator can include a three-layer design, with a first layer comprising stainless steel (e.g., forming base 120), a second layer comprising a polyimide (e.g., isolating electrical contacts, and a third layer comprising gold-plated stainless steel.

For instance, in the actuator 100 as shown in FIG. 1, the SMA 110a-b can be engaged to the base (e.g., at 114a-b, 118a-b) at a top or upper surface of the actuator (e.g., a surface facing away from the carriage 104). The SMA can be welded (or soldered) to a top stainless-steel surface (or, in some cases, a gold-plated metal). However, as described in greater detail below, such a configuration can result in lower resiliency of the weld joint due at least to the wire angle and maximum stress occurring at the weld joint as the SMA actuates.

In some instances, a switch, such as a smart lock, or sensor, can be remotely controlled by providing a magnetic field to move a locking or moving mechanism to transition the lock or sensor between a locked (or closed) and unlocked (or open) position. Many locks or sensors can use magnetic sensors to lock/unlock the lock. However, verifying such locks or sensors can be unreliable with magnetic sensors. For example, an outside or unauthorized power source can override the magnetic sensors using large magnetic fields to unlock the lock. In further instances, a switch, can suffer from inconsistent contact resistance hence effecting the indicated status of the switch.

The present embodiments relate to shape memory alloy (SMA) actuators being used as sensors that implement differential resistance to determine if a mechanism has changed positions. In some examples, the SMA wire can actuate a locking mechanism or sensor mechanism and then use differential resistance to sense the status of the mechanisms position.

The SMA sensing designs as described herein can relate to constrained sensors and/or deformed sensors that can use any of a shape memory effect of the SMA wire and/or a super-elastic effect of the SMA wire. The designs as described herein can be unaffected or impervious to external magnetic fields to improve security and unauthorized manipulation for a smart lock, as well as avoiding contact resistance variations typical in most electrical switches. In some instances, the SMA wire can actuate a locking mechanism or act as a sensor mechanism and then use differential resistance to sense a status of the position of the locking mechanism. In some examples, the status of the locking mechanism or sensor mechanism is either open or close. In some examples, the change in position of the locking mechanism is variable. Such a system is both impervious to magnetic fields and avoids contact resistance variations which is common in previous systems.

While a smart lock is used as an illustrative example, the present embodiments are not limited to such examples. However, the present embodiments can relate to movement of a mechanism between different states, such as a valve, for example. Another example is a sensor.

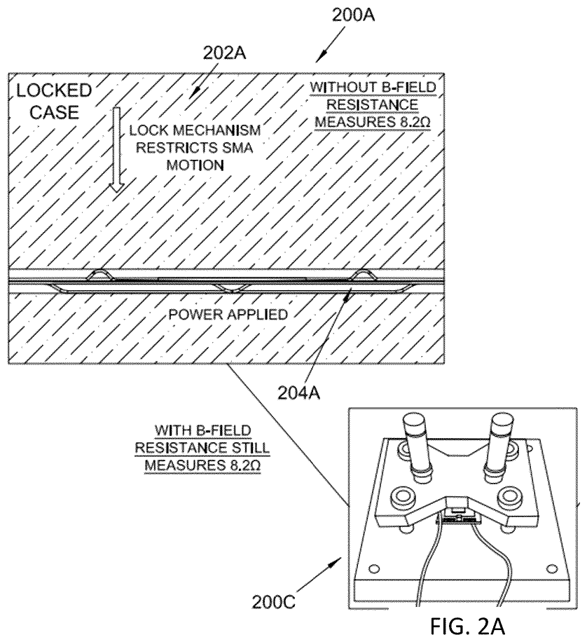

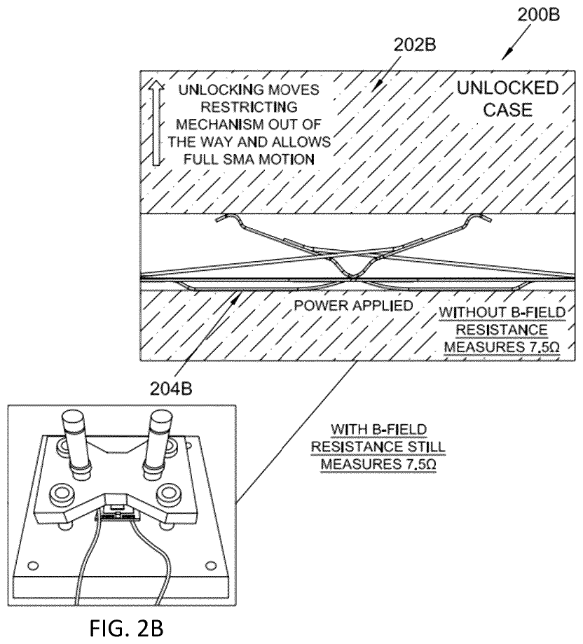

A first example relates to a constrained sensor with a shape memory effect. FIGS. 2A-2B illustrate example sensor designs for the constrained sensor with the shape memory effect. The design in a locked state (e.g., 200A) can include a locking mechanism 202A or moving mechanism, and an actuator 204A. In a locked or closed position, the lock or sensor mechanism 202A can restrict motion of the shape memory alloy (SMA) actuator 204A. Without a magnetic field (B-field) resistance, the actuator can measure 8.2 ohms. With a B-field resistance, the actuator can still measure 8.2 ohms, indicating that with an external magnetic field (such as provided by device 200C), the actuator and/or the lock or sensor mechanism is not impacted by the magnetic field.

In an unlocked or open state (e.g., 200B), the lock mechanism 202B or sensor can be in a position away from the actuator 204B, allowing full SMA motion of the actuator. Without a B-field, the actuator can measure 7.5 ohms. With the B-field, the actuator can still measure 7.5 ohms and thus not be impacted by the magnetic field. The SMA sensor resistance can delineate between the locked and unlocked position.

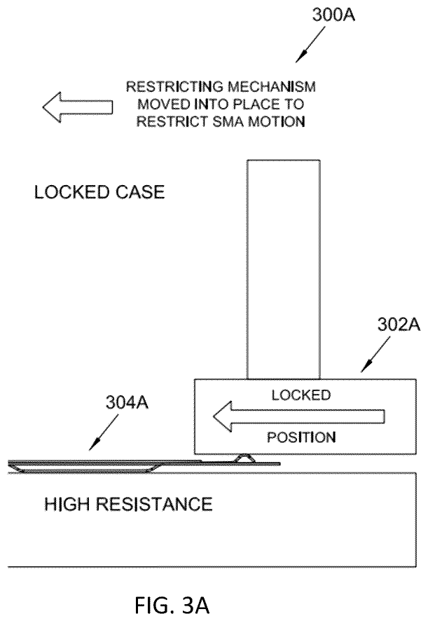

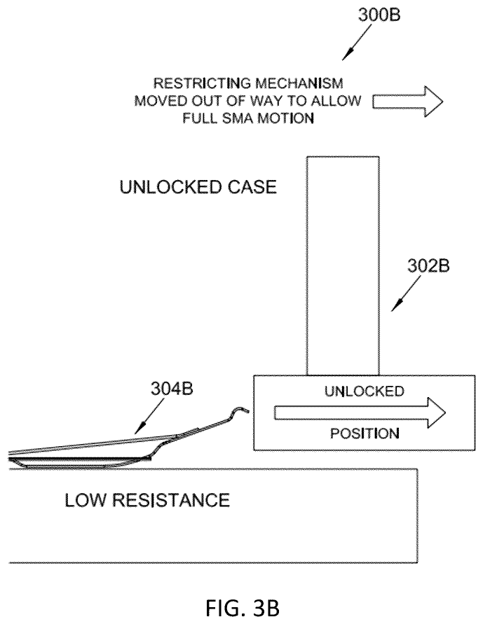

A second example design includes a constrained sensor with a shape memory effect. FIGS. 3A-B illustrate example states 300A, 300B of the constrained sensor with the shape memory effect. As shown in FIG. 3A, in a locked position (e.g., in 300A), the locking mechanism 302A can be disposed over a free end of the SMA actuator 304A, preventing actuation of the SMA actuator 304A. In an unlocked or open position, the locking or moving mechanism 302B can be moved away from the SMA actuator 304B, allowing actuation of the actuator 304B. The SMA sensor resistance can delineate between the locked and unlocked position or open or closed position.

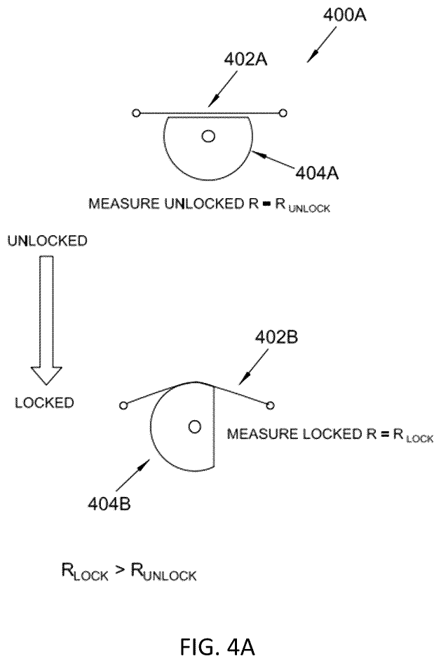

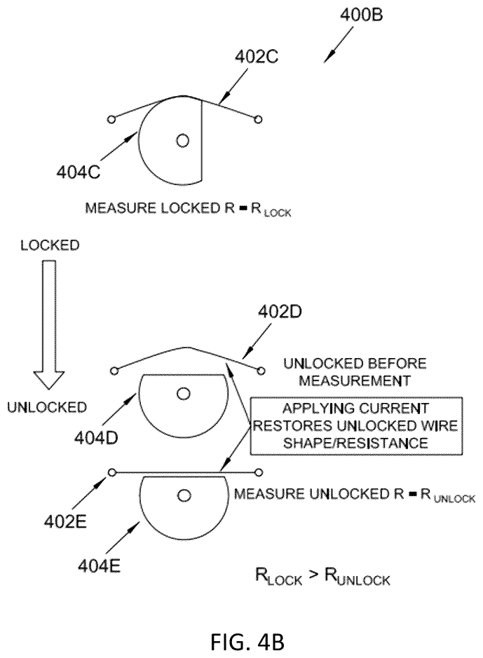

In another example embodiment, the SMA sensor can include a deformed sensor with shape memory effect. FIGS. 4A-B illustrate example views 400A-B of an SMA wire 402A-E and a locking mechanism 404A-E or moving mechanism. The actuator can include an SMA wire with fixed points fixing the SMA wire and a locking/unlocking mechanism that can strain the wire, leading to resistance change. An applied current can heat the wire to return to its original shape, which can be referred to as a shape memory effect.

In a first instance 400A, the SMA wire 402A can be adjacent to a flat portion of a circular locking mechanism 404A, which provides little or no strain to the SMA wire (Runlock). In a locked position, the SMA wire 402B can contact the locking mechanism 404B, providing a strain to the SMA wire 402B. The resistance of the SMA wire in the locked position (Rlock) can be greater than resistance Runlock. The locking or moving mechanism can be substantially circular with a flat portion, which can allow for modifying a resistance to the SMA wire.

In the application, the binary examples of locked and unlocked are not intended to be limiting. Any position change can be made using the systems and methods here, from locked, unlocked, and any variation in between. Any variation percentage can be achieved such as a dynamic open/closed, or 1st position/2nd position, or any intermediary position as described.

In a second instance 400B, the SMA wire 402C can be in contact with the locking mechanism 404C, or moving mechanism, providing a resistance Rlock. Transitioning to the unlocked position, the locking mechanism 404D can rotate, disconnecting from the SMA wire 402D. Further, applying a current restores the unlocked wire shape and resistance of the SMA wire 402D to an unlocked position of the SMA wire 402E.

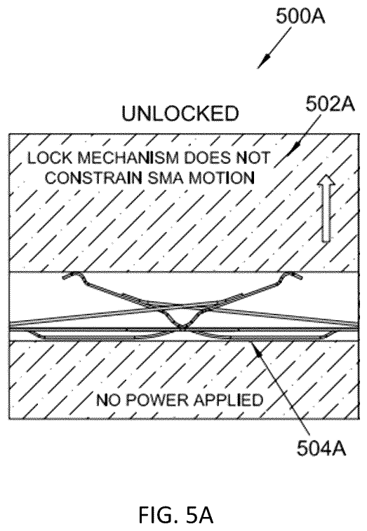

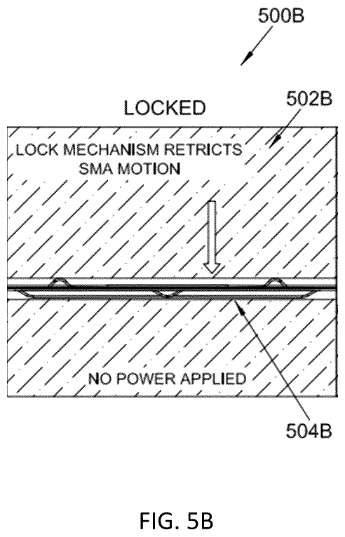

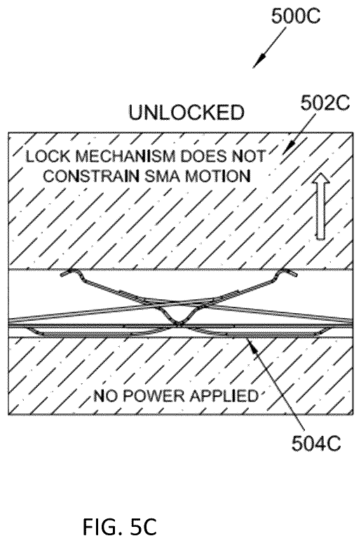

In another example embodiment, a constrained sensor with super-elastic effect is described. FIGS. 5A-C illustrate example views of a constrained sensor with a super-elastic effect. In a first unlocked position (500A), the lock mechanism 502A may not constrain motion of the SMA actuator 504A. When the locking mechanism is out of the way, the super-elastic SMA sensor can be in a low resistance state.

In a locked position (500B) the locking mechanism 502B can restrict motion of the SMA sensor 504B. When the locking or moving mechanism pushes down the Super-Elastic SMA sensor, the sensor can have a high resistance.

In a second unlocked position (500C) transitioning from a locked position, or closed position, the locking mechanism 502C or moving mechanism may not constrain motion of the SMA sensor 504C. When the locking mechanism is removed, the SMA sensor can spring back into the high resistance state.

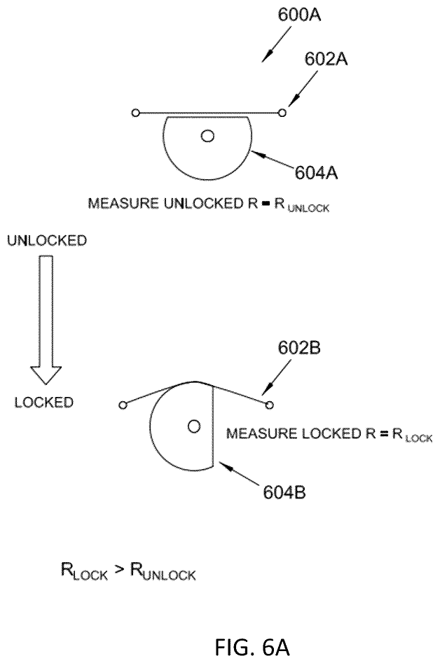

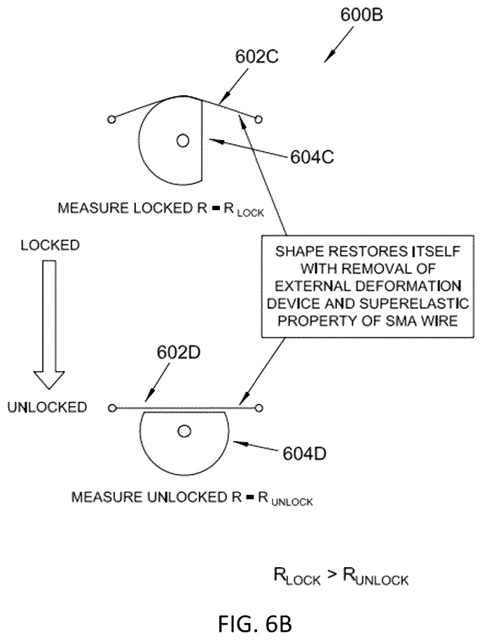

In another example embodiment, a design can include a deformed sensor with a super-elastic effect. FIGS. 6A-B illustrate example positions of a deformed sensor with a super-elastic effect. By adjusting SMA alloy composition, the transition temperature of an SMA material can be adjusted. As such, an SMA sensor can operate in a super-elastic state, which can mean that other sensors may not require the applied current to restore the unlocked resistance and can enable a lower power design.

In FIG. 6A, a first position 600A illustrates a sensor in an unlocked position, or open position, with the locking or moving mechanism 604A not being in contact with an SMA wire 602A. In a locked position, the locking mechanism 604B can contact the SMA wire 602B, causing a resistance (Rlock) to be greater than or change a resistance at the unlocked position (Runlock) or open position.

In a second instance 600B, the locking mechanism 604C can contact the SMA wire 602C. The shape of SMA wire can restore itself with removal of external deformation device and super-elastic property of SMA wire. For example, in the unlocked position, or open position, the SMA wire 602D can restore itself in the unlocked position or open position and not in contact with the locking mechanism 604D.

An example design can include constrained sensors and a shape memory effect. In such examples, an SMA sensor can operate in the shape memory effect region, where a resistance difference between locked and unlock states can be due to the locking mechanism or moving mechanism constraining or not constraining the sensor motion. Another example design can include constrained sensors and super elastic effect. In this example, an SMA sensor, operating in the super elastic effect region, where the resistance difference between locked and unlock states, or open or closed states, is due to the locking mechanism constraining or not constraining the sensor motion.

Another example design can include deformed sensors and a shape memory effect. In this example, an SMA sensor can operate in the Shape Memory Effect region where resistance difference between locked and unlocked states is due to a deformation of the SMA wire by a locking mechanism and the recovered shape of the SMA. Another example design can include deformed sensors and super elastic effect. In this example, an SMA sensor can operate in the Super Elastic Effect region, where the resistance difference between locked and unlocked states, or open or closed states, can be due to a deformation of the SMA wire by a locking mechanism.

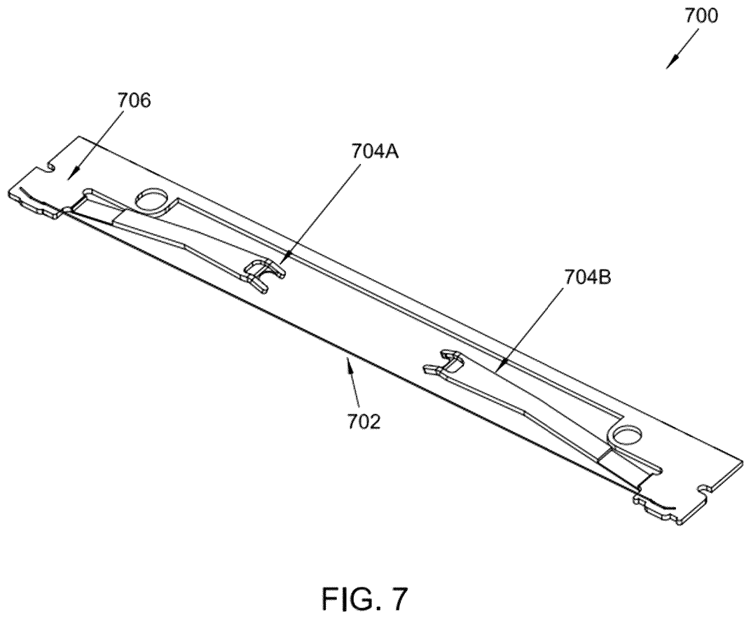

In a first example embodiment, a bimorph actuator as described herein can be used as an SMA sensor as described herein. However, other embodiments can include other actuator types. For example, another example actuator can include an actuator with multiple arms at opposing ends facing one another, which may be referred to as a buckler actuator. FIG. 7 illustrates an example buckler actuator 700. The buckler actuator 700 can include a base 706 and multiple arms 704A-B. The arms 704A, 704B can each be fixed to a base 706 at opposing ends and be facing one another. The actuator 700 can also include an SMA wire 702 disposed across the actuator. Additionally or alternatively, in some embodiments, a Super-Elastic effect of the SMA wire 702 is used.

In another example design, the SMA actuator can include an inline bimorph actuator. FIG. 8 illustrates an example inline bimorph actuator 800. As shown in FIG. 8, the actuator 800 can include a fixed portion 808 affixed to a base and free ends 804A, 804B, with actuator arms 806A-B disposed between the fixed portion 808 and free ends 804A-B. Further, the SMA wire 802 can be disposed between the free ends 804A-B of the arms 806A, 806B. Additionally or alternatively, in example embodiments using a Super-Elastic effect of wire 802, the actuator would be in an actuated state (i.e. 804A and 804B would be elevated in a positive direction in FIG. 8).

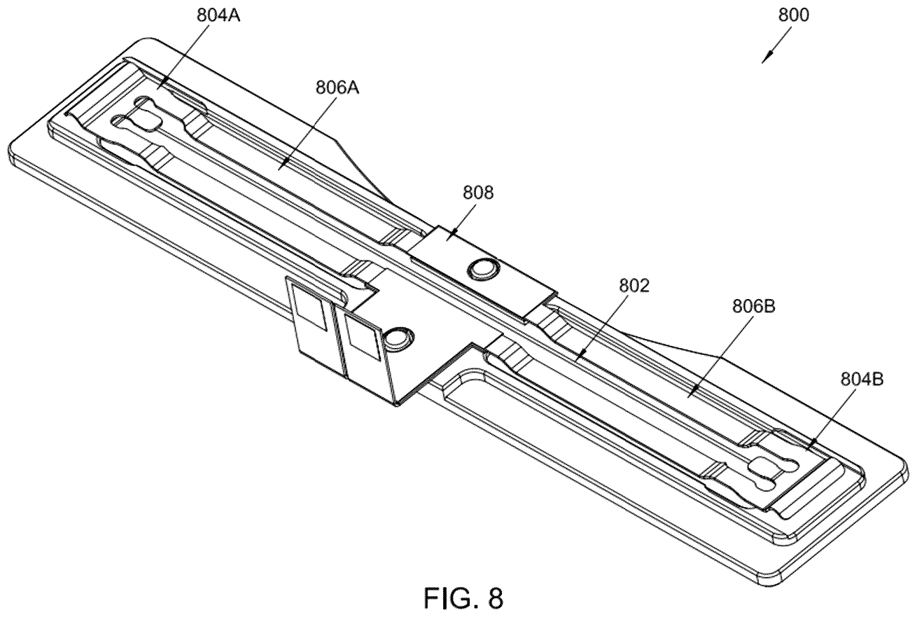

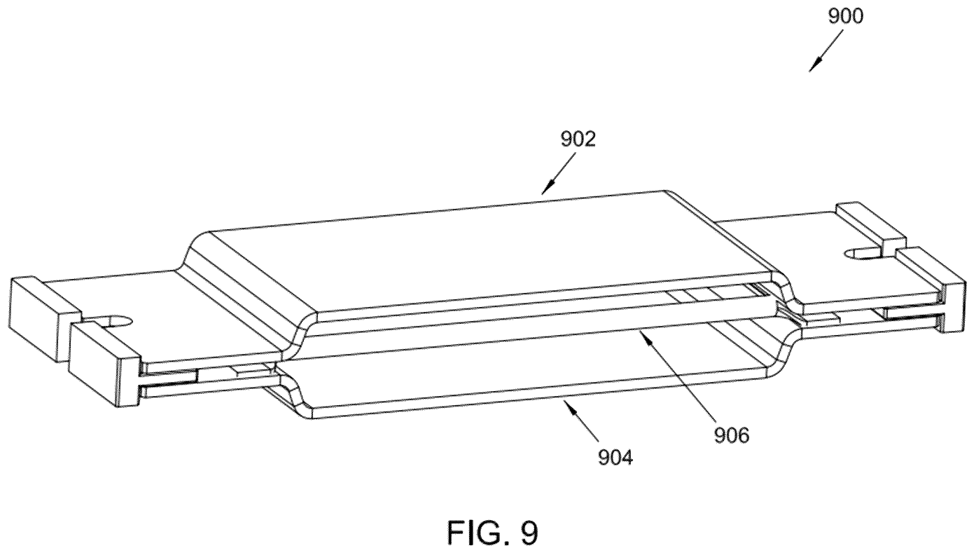

In another example design, an SMA sensor can include a bridge sensor. FIG. 9 is an example bridge sensor 900. The bridge sensor 900 can include a first end 902 and a second end 904, with an SMA wire 906 disposed between the first end 902 and second end 904. These embodiments can be either Shape Memory Effect based, or Super-Elastic Effect based.

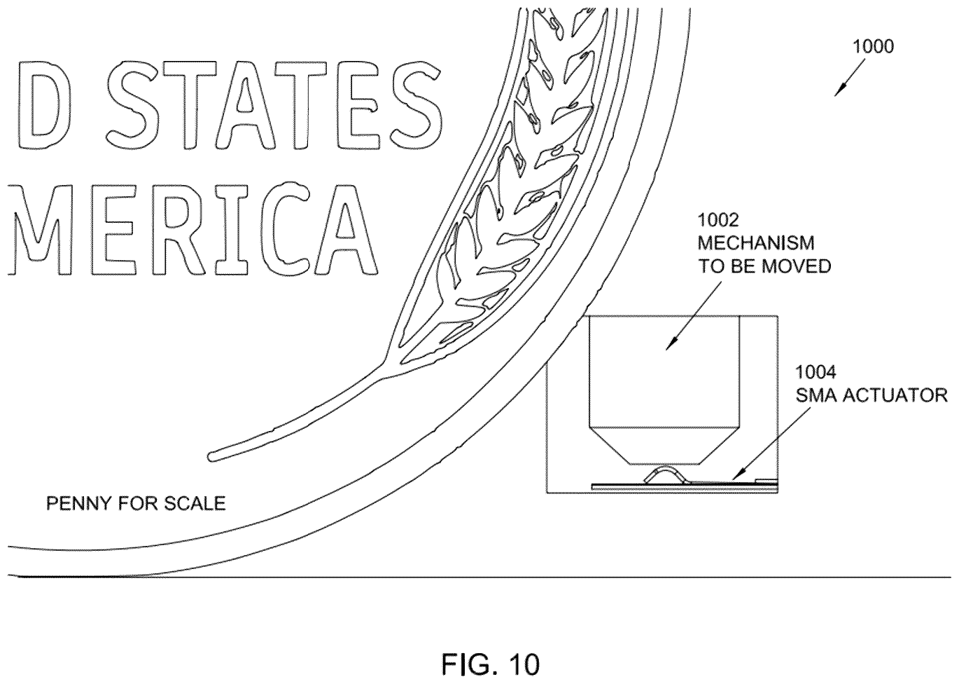

FIG. 10 illustrates an example 1000 for SMA actuation with sensing a status of a mechanism. As shown in FIG. 10, an SMA actuator 1004 and a mechanism 1002 are shown. The SMA actuator can move the mechanism. Based on the differential resistance of the SMA actuator, the mechanism's position status can be determined. The SMA actuator moving the mechanism can be based on the differential resistance of the SMA actuator, and the position of the mechanism can be indicated.

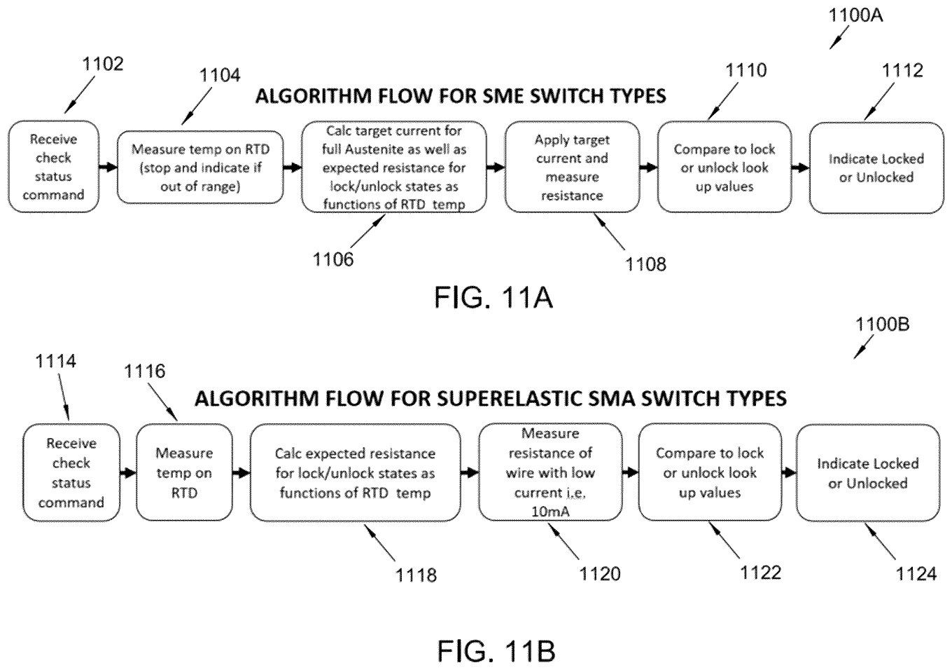

FIGS. 11A-B illustrates example algorithms for an SMA sensor to indicate whether a locking mechanism is in a locked or unlocked position. A first example algorithm 1100A relates to shape memory effect (SME) sensor types. A computing system or other electronic system connected to one or more measurement devices and/or the SMA sensor can perform the algorithms as described here. At 1102, a check status command can be received. At 1104, a temperature on the RTD can be measured, where the system can stop and indicate if the device is out of range.

At 1106, a target current for full Austenite can be calculated as well as expected resistance for lock/unlock states as functions of the RTD temp. At 1108, a target current can be applied, and resistance can be measured. At 1110, the resistance can be compared to lock or unlock look up resistance values to determine whether the lock is locked or unlocked based on the resistance value. At 1112, the system can indicate whether the lock is locked or unlocked, or sensor is open or closed.

A second algorithm flow 1100B can relate to super-elastic SMA sensor types. At 1114, a check status command can be received. At 1116, a temperature on the RTD can be measured. At 1118, an expected resistance for unlock/locked states, or open or closed states, can be calculated as functions of the RTD temperature. At 1120, a resistance of the SMA wire with a low current (e.g., 11 milliamps mA) can be measured. At 1122, the measured resistance can be compared to lock or unlock look up resistance, or open or closed look up resistance values to determine whether the lock is locked or unlocked, or open or closed, based on the resistance value. At 1124, the system can indicate whether the lock is locked or unlocked, or sensor is open or closed.

In some instances, unlock and lock states or open or closed states, can be in different environments, so the algorithm may not be a simple percentage change or threshold algorithm, but a target resistance algorithm taking temperature (and potentially stress) into account. To capture the temperature variable between lock and unlock times, a Resistance Temperature Device (RTD) can be used. That RTD measurement can gate the locking/unlocking or opening/closing based on a working range of the lock or sensor. Even so, in the super-elastic designs, the SMA wire can operate in its super-elastic region i.e. operating temps of Av<T<Md. In that region, the temperature coefficient of resistance can be on the order of 0.0002/C. With a super-elastic switch:

$${R}_{constrained \_ 23 C} = 8. Ω thus {R}_{constrained \_ - 20 C} = 7.93 Ω and$$

$${R}_{constrained \_ 60 C} = 8.06 Ω$$

$${R}_{unconstrained \_ 23 C} = 7.27 Ω thus {R}_{unconstrained \_ - 20 C} = 7.21 Ω and$$

$${R}_{unconstrained \_ 60 C} = 7.32 Ω$$

The populations may not overlap which can help to resolve the locked and unlocked states or open or closed states. Even with 200C and −78C (dry ice) there is no population overlap (7.53 Ohm unconstrained vs. 7.84 Ohm constrained). These can assume that such a low temp SMA alloy exists, its Austenite TCR is 0.0002/C and Md is above 200C.

With an SME type switch, this can operate in the Austenite region since resistance can be measured with a current level high enough to enable the shape memory effect.

A difference with the SME switch can be the need to calculate at target current for a given environment temperature to achieve Austenite phase and/or the application of the target current to the SMA wire while measuring resistance. To capture the temperature variable between lock and unlock times, the RTD measurement can be used to gate the locking/unlocking or opening/closing based on a working range of the lock or sensor.

In another example, a near-field communication (NFC) enabled phone can power a control integrated circuit. A process for an SMA switch to interface with a control IC GPIO can include establishing a secure communication with the phone and charge energy harvesting caps. A motor can be driven to lock or unlock states, and the SMA switch can allow for verifying whether the interface is in the locked or unlocked position.

In another example, temperature verification can include verifying how temperature can impact the use of the designs as described herein. For instance, an applied current can be calculated to achieve similar wire temps in various environments. A test sample (without constraint) can be set up in temp environments and a resistance with calculated current can be measured. The sample and retest can be constrained in environments, and a ΔR/R can be calculated for with and without constraint for environments.

This can achieve similar % resistance changes at −20C to 60C temp range by adjusting current by +/−13%. The SMA Switch sensing concepts can be able to be used in −20C to 60C environments.

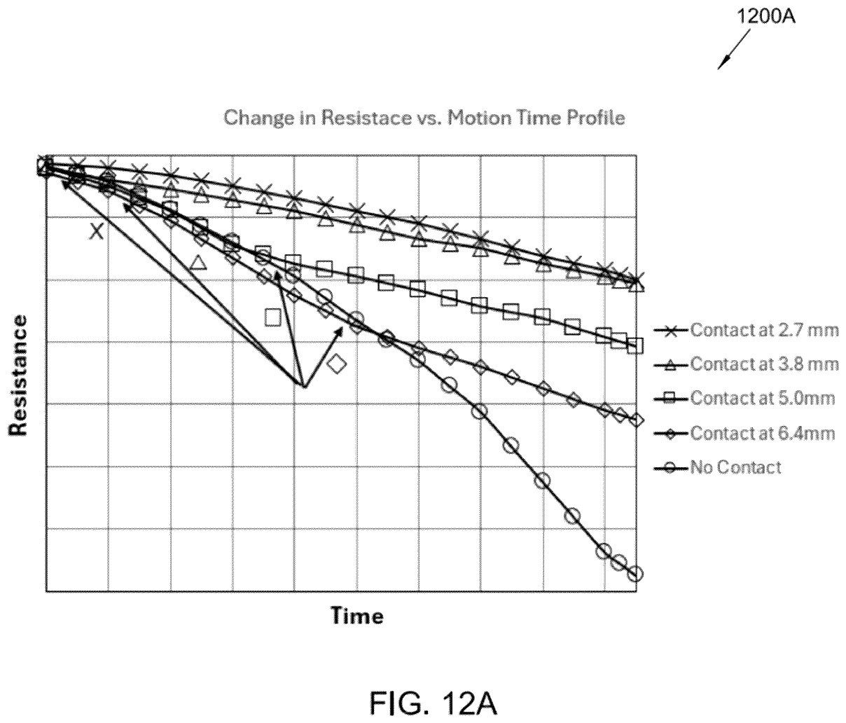

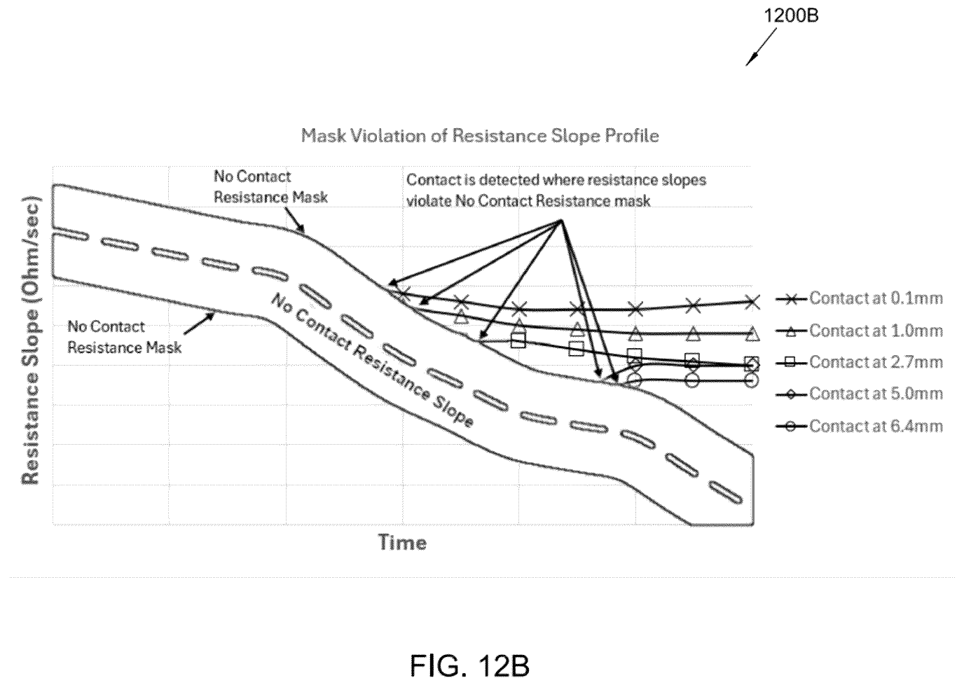

FIG. 12A is a graphical representation 1200A of an example change in resistance over time for different actuator groups. As shown in FIG. 12A, contact for the different actuator groups can be detected at different positions due to slope changes in the groups of actuators.

FIG. 12B is a graphical representation 1200B of an example mask violation of resistance slope profile. As shown in FIG. 12B, contact can be detected at the no contact masks at different times depending on the actuator group.

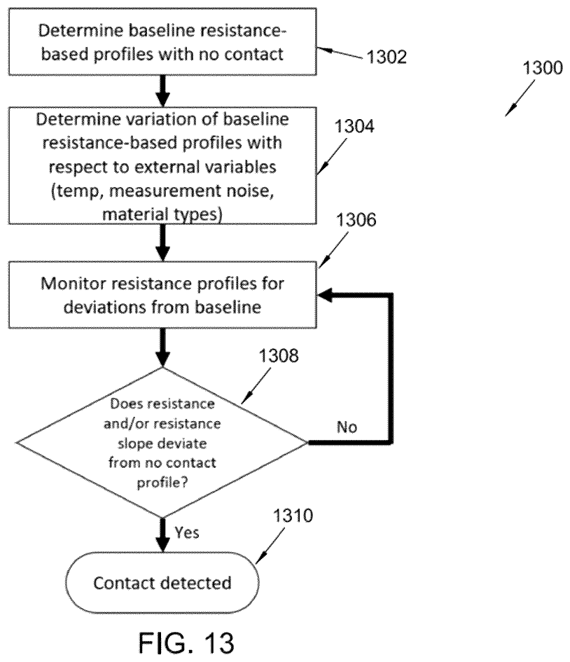

FIG. 13 is an example flow process 1300 for contact sensing of an SMA actuator as described herein. At 1302, a baseline resistance-based profile of an actuator with no contact can be determined. The resistance-based profile with no contact can represent resistance-related data values when the actuator is not in contact with a contact element (e.g., a switch). For instance, a resistance or voltage detected in the actuator when the actuator is not in contact with a contact element can be used to generate the resistance-based profile.

At 1304, a variation of the baseline resistance-based profiles can be determined with respect to external variables. The external variables can include temperature, measurement noise, material types, etc. The variation of the baseline can identify differing values that can be attributed to changing external variables without indicating that contact has been detected. For example, a change in external temperature can change a resistance or voltage in the actuator but this change may not be attributed to the change in state (e.g., contact being detected).

At 1306, resistance variables for deviations from the baseline can be monitored. At 1308, it can be determined whether the resistance or resistance slope deviates from the no contact profile. The deviation from the no contact profile can be indicative that contact is detected. This can include periodically determining whether the resistance or resistance slope deviates from the baseline profile with the variation in the baseline with respect to external variables taken into account.

At 1310, if it is determined that the resistance or resistance slope deviates from the no contact profile, contact can be detected. For instance, if a contact element contacts the actuator, the resistance or resistance slope of the actuator can change more than a threshold amount, indicating that contact has been made.

If it is determined that the resistance or resistance slope does not deviate from the no contact profile, the monitoring as described with respect to 1306 is repeated. This can be repeated periodically to determine whether contact has been made, such as at 1310.

In an example embodiment, a sensing system is described. The sensing system can include a moving mechanism configured to be disposed in any of a closed position and an open position. The sensing system can also include a shape memory alloy (SMA) sensor configured to move in response to a current being applied to the SMA sensor.

The moving mechanism can be configured to restrict movement of the SMA sensor or change a resistance of the SMA sensor in the closed position. A closed position resistance of the SMA sensor when the moving mechanism is in the closed position can be different than an open position resistance of the SMA sensor when the moving mechanism is in the open position.

In some instances, the closed position resistance or the open position resistance of the SMA sensor is not modified by any external magnetic field applied to the sensing system.

In some instances, the SMA sensor is a bimorph actuator comprises a first bimorph arm including a fixed end fixed to a base, a free end that is unfixed, and an SMA wire disposed from at least the fixed end to the free end, wherein the free end is configured to move in a positive direction in response to the current being applied to the SMA wire.

In some instances, the bimorph actuator further comprises a second bimorph arm with a fixed end fixed to the base and a free end disposed in a direction opposite to a direction of the free end of the first bimorph arm, and wherein the SMA wire is disposed from the free end of the first bimorph arm to the free end of the second bimorph arm.

In some instances, the moving mechanism, in the open position, is configured to move laterally away from the SMA sensor to allow free movement of the SMA sensor in response to the current being applied to the SMA sensor.

In some instances, the SMA sensor is an SMA element disposed between anchor points anchored to a base.

In some instances, the moving mechanism is substantially circular with a flat portion, wherein the moving mechanism in the closed position comprises a circular portion of the moving mechanism being in contact with the SMA element, thereby increasing a resistance of the SMA element and deforming the SMA element, and wherein the moving mechanism in the open position includes the flat portion being in parallel with the SMA element, changing the resistance of the SMA element.

In some instances, responsive to the moving mechanism moving from the closed position to the closed position, the current applied to the SMA element restored an original shape of the SMA element.

In some instances, the SMA sensor is a buckler actuator comprising a first buckler arm including a fixed end fixed to a base at a first end of the base and a free end that is unfixed. The buckler actuator can also include a second buckler arm including a fixed end fixed to a second end of the base, a free end that is unfixed, wherein the free end of the second buckler arm is directed toward the free end of the first buckler arm, and an SMA wire disposed between the first end of the base and the second end of the base.

In some instances, the SMA sensor is a bridge sensor comprising a first portion disposed from a first end of a base to a second end of the base, a second portion disposed in parallel with the first portion and fixed at each of the first end of the base and the second end of the base, and an SMA wire disposed between an opening formed between the first portion and the second portion and extending between the first end of the base and the second end of the base.

In some instances, the SMA use a shape memory effect of the SMA wire, or, a super-elastic effect of the SMA wire.

In another example embodiment, a device is described. The device can include a moving mechanism configured to be disposed in any of a closed position and an open position and a shape memory alloy (SMA) actuator. The SMA actuator can include a first actuator arm including a fixed end fixed to a base, a free end that is unfixed, and an SMA wire disposed from at least the fixed end to the free end. The free end can be configured to move in a positive direction in response to a current being applied to the SMA wire. The moving mechanism can be configured to restrict movement of the SMA actuator or change a resistance of the SMA actuator in the closed position, and wherein a closed position resistance of the SMA actuator when the moving mechanism can be in the closed position is different than an open position resistance of the SMA actuator when the moving mechanism is in the open position.

In some instances, the closed position resistance or the open position resistance of the SMA sensor is not modified by any external magnetic field applied to the sensing system.

In some instances, the SMA actuator further comprises a second actuator arm with a fixed end fixed to the base and a free end disposed in a direction opposite to a direction of the free end of the first actuator arm, and wherein the SMA wire is disposed from the free end of the first actuator arm to the free end of the second actuator arm.

In some instances, the moving mechanism, in the open position, is configured to move laterally away from the SMA sensor to allow free movement of the SMA sensor in response to the current being applied to the SMA sensor.

In some instances, the SMA actuator is a buckler actuator comprising a second actuator arm including a fixed end fixed to a second end of the base, a free end that is unfixed, wherein the free end of the second buckler arm is directed toward the free end of the first buckler arm, and an SMA wire disposed between the first end of the base and the second end of the base.

In some instances, the SMA use a shape memory effect of the SMA wire, or, a super-elastic effect of the SMA wire.

In another example, a sensor is described. The sensor can include a moving mechanism configured to be disposed in any of a closed position and an open position, wherein the moving mechanism is substantially circular with a flat portion. The sensor can also include a shape memory alloy (SMA) element configured to move in response to a current being applied to the SMA element, wherein the moving mechanism is configured to change a resistance of the SMA element in the closed position, and wherein a closed position resistance of the SMA element when the moving mechanism is in the closed position is different than an open position resistance of the SMA element when the moving mechanism is in the open position.

In some instances, the SMA element disposed between anchor points anchored to a base.

In some instances, the moving mechanism in the closed position comprises a circular portion of the moving mechanism being in contact with the SMA element, thereby changing a resistance of the SMA element and deforming the SMA element, and wherein the moving mechanism in the open position includes the flat portion being in parallel with the SMA element, changing the resistance of the SMA element.

In some instances, responsive to the moving mechanism moving from the closed position to the closed position, the current applied to the SMA element restored an original shape of the SMA element.

In some instances, a state of the sensor can be determined based on comparing the closed position resistance of the SMA element or the open position resistance of the SMA element in relation to resistance values in a lookup table.

In some instances, the SMA use a shape memory effect of the SMA wire, or, a super-elastic effect of the SMA wire.

In another example, a method of using a shape memory alloy (SMA) actuator as a sensor is provided. The method can include sensing a first resistance from an SMA wire. The method can also include sensing a second resistance from the SMA wire. The method can also include determining a differential resistance between the first resistance and second resistance of the SMA wire. The method can also include actuating a moving mechanism with the SMA wire. The method can also include determining, based on the sensed differential resistance, a change in position of the moving mechanism.

In some instances, the SMA is a constrained sensor or deformed sensor.

In some instances, the SMA use a shape memory effect of the SMA wire, or, a super-elastic effect of the SMA wire.

In some instances, the change in position of the moving mechanism is either open or closed.

In some instances, the change in position of the moving mechanism is variable.

In some instances, a method of using a shape memory alloy (SMA) as a sensor is provided. The method can include sensing a first resistance from an SMA wire. The method can also include sensing a second resistance from the SMA wire. The method can also include determining a differential resistance between the first resistance and second resistance of the SMA wire. The method can also include determining, based on the sensed differential resistance, a change in position of the moving mechanism.

In some instances, the SMA is a constrained sensor or deformed sensor.

In some instances, the SMA use a shape memory effect of the SMA wire, or, a super-elastic effect of the SMA wire.

In some instances, the change in position of the moving mechanism is either open or closed.

In some instances, the change in position of the moving mechanism is variable.

It will be understood that terms such as “top,” “bottom,” “above,” “below,” and x-direction, y-direction, and z-direction as used herein as terms of convenience that denote the spatial relationships of parts relative to each other rather than to any specific spatial or gravitational orientation. Thus, the terms are intended to encompass an assembly of component parts regardless of whether the assembly is oriented in the particular orientation shown in the drawings and described in the specification, upside down from that orientation, or any other rotational variation.

It will be appreciated that the term “present invention” as used herein should not be construed to mean that only a single invention having a single essential element or group of elements is presented. Similarly, it will also be appreciated that the term “present invention” encompasses a number of separate innovations, which can each be considered separate inventions. Although the present invention has been described in detail with regards to the preferred embodiments and drawings thereof, it should be apparent to those skilled in the art that various adaptations and modifications of embodiments of the present invention may be accomplished without departing from the spirit and the scope of the invention. Accordingly, it is to be understood that the detailed description and the accompanying drawings as set forth hereinabove are not intended to limit the breadth of the present invention, which should be inferred only from the following claims and their appropriately construed legal equivalents.

What is claimed is:

1. A sensing system comprising:
a moving mechanism configured to be disposed in any of a closed position and an open position; and
a shape memory alloy (SMA) sensor configured to move in response to a current being applied to the SMA sensor, wherein the moving mechanism is configured to restrict movement of the SMA sensor or change a resistance of the SMA sensor in the closed position, and wherein a closed position resistance of the SMA sensor when the moving mechanism is in the closed position is different than an open position resistance of the SMA sensor when the moving mechanism is in the open position.

2. The sensing system of claim 1, wherein the closed position resistance or the open position resistance of the SMA sensor is not modified by any external magnetic field applied to the sensing system.

3. The sensing system of claim 1, wherein the SMA sensor is a bimorph actuator comprising:
a first bimorph arm including:
a fixed end fixed to a base;
a free end that is unfixed; and
an SMA wire disposed from at least the fixed end to the free end, wherein the free end is configured to move in a positive direction in response to the current being applied to the SMA wire.

4. The sensing system of claim 3, wherein the bimorph actuator further comprises:
a second bimorph arm with a fixed end fixed to the base and a free end disposed in a direction opposite to a direction of the free end of the first bimorph arm, and wherein the SMA wire is disposed from the free end of the first bimorph arm to the free end of the second bimorph arm.

5. The sensing system of claim 1, wherein the moving mechanism, in the open position, is configured to move laterally away from the SMA sensor to allow free movement of the SMA sensor in response to the current being applied to the SMA sensor.

6. The sensing system of claim 1, wherein the SMA sensor is an SMA element disposed between anchor points anchored to a base.

7. The sensing system of claim 6, wherein the moving mechanism is substantially circular with a flat portion, wherein the moving mechanism in the closed position comprises a circular portion of the moving mechanism being in contact with the SMA element, thereby increasing a resistance of the SMA element and deforming the SMA element, and wherein the moving mechanism in the open position includes the flat portion being in parallel with the SMA element, changing the resistance of the SMA element.

8. The sensing system of claim 7, wherein responsive to the moving mechanism moving from the closed position to the closed position, the current applied to the SMA element restored an original shape of the SMA element.

9. The sensing system of claim 1, wherein the SMA sensor is a buckler actuator comprising:
a first buckler arm including:
a fixed end fixed to a base at a first end of the base; and
a free end that is unfixed;
a second buckler arm including:
a fixed end fixed to a second end of the base; and
a free end that is unfixed, wherein the free end of the second buckler arm is directed toward the free end of the first buckler arm; and
an SMA wire disposed between the first end of the base and the second end of the base.

10. The sensing system of claim 1, wherein the SMA sensor is a bridge sensor comprising:
a first portion disposed from a first end of a base to a second end of the base;
a second portion disposed in parallel with the first portion and fixed at each of the first end of the base and the second end of the base; and
an SMA wire disposed between an opening formed between the first portion and the second portion and extending between the first end of the base and the second end of the base.

11. The sensing system of claim 1 wherein the SMA use a shape memory effect of an SMA wire of the SMA sensor, or, a super-elastic effect of the SMA wire.

12. A device comprising:
a moving mechanism configured to be disposed in any of a closed position and an open position; and
a shape memory alloy (SMA) actuator comprising:
a first actuator arm including:
a fixed end fixed to a base;
a free end that is unfixed; and
an SMA wire disposed from at least the fixed end to the free end, wherein the free end is configured to move in a positive direction in response to a current being applied to the SMA wire, wherein the moving mechanism is configured to restrict movement of the SMA actuator or change a resistance of the SMA actuator in the closed position, and wherein a closed position resistance of the SMA actuator when the moving mechanism is in the closed position is different than an open position resistance of the SMA actuator when the moving mechanism is in the open position.

13. The device of claim 12, wherein the closed position resistance or the open position resistance of the SMA actuator is not modified by any external magnetic field applied to the device.

14. The device of claim 12, wherein the SMA actuator further comprises:
a second actuator arm with a fixed end fixed to the base and a free end disposed in a direction opposite to a direction of the free end of the first actuator arm, and wherein the SMA wire is disposed from the free end of the first actuator arm to the free end of the second actuator arm.

15. The device of claim 12, wherein the moving mechanism, in the open position, is configured to move laterally away from the SMA actuator to allow free movement of the SMA actuator in response to the current being applied to the SMA actuator.

16. The device of claim 12, wherein the SMA actuator is a buckler actuator comprising:
a second actuator arm including
a fixed end fixed to a second end of the base;
a free end that is unfixed, wherein the free end of the second buckler arm is directed toward the free end of the first actuator arm; and
an SMA wire disposed between the first end of the base and the second end of the base.

17. The device of claim 12 wherein the SMA use a shape memory effect of the SMA wire, or, a super-elastic effect of the SMA wire.

18. A sensor comprising:
a moving mechanism configured to be disposed in any of a closed position and an open position, wherein the moving mechanism is substantially circular with a flat portion; and
a shape memory alloy (SMA) element configured to move in response to a current being applied to the SMA element, wherein the moving mechanism is configured to change a resistance of the SMA element in the closed position, and wherein a closed position resistance of the SMA element when the moving mechanism is in the closed position is different than an open position resistance of the SMA element when the moving mechanism is in the open position.

19. The sensor of claim 18, wherein the SMA element disposed between anchor points anchored to a base.

20. The sensor of claim 18, wherein the moving mechanism in the closed position comprises a circular portion of the moving mechanism being in contact with the SMA element, thereby changing a resistance of the SMA element and deforming the SMA element, and wherein the moving mechanism in the open position includes the flat portion being in parallel with the SMA element, changing the resistance of the SMA element.
